(19) United States
(12) Patent Application Publication
(10) Pub. No.: US 2011/0010911 A1
(43) Pub. Date: Jan. 20, 2011

(54) METHODS AND APPARATUS FOR LIGHT HARVESTING IN DISPLAYS

(75) Inventors: Marc A. Baldo, Lexington, MA (US); Carlijn L. Mulder, Boston, MA (US); Carmel Rotschild, Brookline, MA (US)

Correspondence Address: K&L Gates LLP, STATE STREET FINANCIAL CENTER, One Lincoln Street, BOSTON, MA, 02111-2950, US

(73) Assignee: MASSACHUSETTS INSTITUTE OF TECHNOLOGY, Cambridge, MA (US)

(21) Appl. No.: 12/821,932

(22) Filed: Jun. 23, 2010

Related U.S. Application Data
(60) Provisional application No. 61/220,115, filed on Jun. 24, 2009.
(60) Provisional application No. 61/220,145, filed on Jun. 24, 2009.

(51) Int. Cl. B23P 11/00; H01L 31/055; G02B 26/00; B05D 5/06

(52) U.S. Cl. 29/428; 136/247; 359/237; 427/74

(57) ABSTRACT

Methods and apparatuses for harvesting light from displays. In one embodiment, the invention relates to a substrate having a first and a second surface, an edge and a luminescent dye. A photovoltaic transducer is positioned adjacent the substrate. Light passing through both the first and second surfaces of the substrate is polarized and light constrained within and traveling through the substrate interacts with the photovoltaic transducer to produce electric current. In one embodiment, the method of harvesting light from an illuminated electronic display including the steps of providing a light source, providing a substrate having a first and a second surface and an edge; and a luminescent dye; and providing a photovoltaic transducer positioned adjacent the substrate. Light passing through both the first and second surfaces of the substrate is polarized, and light constrained within and traveling through the substrate interacts with the photovoltaic transducer to produce electric current.

### REFERENCE TO GOVERNMENT FUNDING

This invention was made with government support under grant number DE-FG02-07ER46474 awarded by the U.S. Department of Energy. The government has certain rights in the invention.

### FIELD OF THE INVENTION

The invention relates generally to the field of energy conservation and more specifically to the conversion of unused light into electricity.

### RELATED APPLICATIONS

The present application claims priority to a provisional application entitled “Luminescent Solar Concentrators for Energy Harvesting in Displays” filed on Jun. 24, 2009 and having Ser. No. 61/220,115, and provisional application “Luminescent Solar Concentrators for Energy Harvesting in Displays” filed on Jun. 24, 2009 and having Ser. No. 61/220,145.

### BACKGROUND OF THE INVENTION

An electronic display is a significant user of electrical energy and is a major contributor to a decrease in battery life in mobile devices and an inefficient user of electricity in devices connected to the electrical grid. Many standard LCD displays as known to the prior art (FIG. 1) include a backlight source 10, a diffuser 14, a brightness enhancing film 18, first and second polarizers 22, 26, a modulator 30 and a viewing angle enhancer 34. The modulator 30 includes a thin-film-transistor (TFT) layer 38, a liquid crystal layer 42 and a color filter layer 46.

In operation, in one type of display, light from the backlight source 10 is directed toward the modulator 30. The diffuser film 14 diffuses the light from the backlight source 10 to make it more uniform and the brightness enhancing film 18 directs more of the light from the diffuser 14 in the direction of the modulator 30. The first polarizer 22 polarizes that light to a specific preferred polarization. Light having a different polarization from the preferred polarization of the first polarizer 22 is absorbed by the polarizer 22 and turned into waste heat. It should be noted that this arrangement not only affects light coming from the backlight source 10 but also must absorb ambient light otherwise the display contrast will be destroyed. This provides another opportunity to harvest energy.

Polarized light arriving at the modulator 30 passes through the TFT layer 38 and enters the liquid crystal layer 42. The liquid crystal in the layer is made up extended nemetic liquid crystal molecules which align in a specific direction due to the presence of an electric field produced when the TFT transistors in the TFT layer 38 turn on. The liquid crystal molecules in one alignment allow the light to pass with change in polarization. In a second alignment, the liquid crystal molecules do not affect the polarization of the light passing through. The light then passes through the color filter 46 which has red 50, green 54 and blue 58 sections (if a color display) and otherwise does not pass through a color filter if the device is black and white. Each group of red green blue sections corresponds to one pixel 62, 62′, 62″ (generally 62).

Light coming from the modulator 30 then passes through the viewing angle enhancer 34 to brighten the image, reduce glare and improve off-angle viewing. Light then passes to the second polarizer 26. In one type of display, the second polarizer 26 is oriented at right angles to the first polarizer 22. As a result, light that passes from the first polarizer 22 through the modulator 30 unaffected to the second polarizer 26 will be blocked and will appear as black. Light whose polarization is changed by the modulator 30 to match the orientation of the second polarization filter 26 will pass through to the viewer and will appear as the color whose filter section 50, 54, 58, it passed through. Again, light not being allowed to pass through the second polarizer 26 is turned to waste heat.

FIG. 2 depicts the percent absorption of polarized light reaching a polarizer (curve 70) whose polarization axis orientation is perpendicular to the orientation of the electric field vector of the light. Curve 74 is the percent absorption of light reaching a polarizer whose polarization axis orientation is parellel to orientation of the electric field vector of the light. Note that substantially all the light from the polarizer whose polarization axis orientation is perpendicular to the electric field vector of the light (curve 70) is absorbed and turned to heat. Thus, light energy is further wasted within the polarizers of the display.

The present invention reduces the amount of energy lost to waste heat in polarizers, thereby increasing the efficiency of the display

### SUMMARY OF THE INVENTION

The present invention relates generally to methods and apparatuses for harvesting light from displays. In one embodiment, the invention relates to a light concentrator including a substrate having a first surface, a second surface, an edge; and a luminescent dye. The concentrator includes a photovoltaic transducer positioned adjacent the substrate of the light concentrator. The index of refraction of the substrate is greater than the refractive index of air. Light passing through both the first and second surfaces of the substrate is polarized. Light constrained within and traveling through the substrate of the light concentrator interacts with the photovoltaic transducer to produce electric current.

In another embodiment, the luminescent dye comprises a plurality of different dye molecules. In yet another embodiment, the photovoltaic transducer is located at the edge of the substrate. In still yet another embodiment, the photovoltaic transducer is located on one of the first and second surfaces of the substrate and the index of refraction of the photovoltaic transducer is such that light traveling in the substrate escapes the surface of the substrate and enters the photovoltaic transducer. In another embodiment, the molecules of the dye are coated on one of the surfaces of the substrate such that the longitudinal axis of the dipole of each of the molecules of the dye lies in the plane of the surface and parallel to the axis of the dipole of the other molecules of the dye.

In another embodiment, the luminescent dye is located on at least one of the first surface and the second surface of the substrate. In still yet another embodiment, the luminescent dye is located within the substrate. In another embodiment, the substrate is formed by mixing the dye with the substrate material during formation and stretching the resulting substrate. In yet another embodiment, the molecules of a liquid crystal/dye mixture can be coated on a pre-rubbed substrate which has been coated with an alignment layer such as polyimide. In yet another embodiment, the dye is selected from the group consisting of the light harvesting electronic display of claim 1 wherein the dye is selected from the group consisting of rare earth phosphors, organometallic complexes, porphyrins, perylene and its derivatives, organic laser dyes, FL-612 (Luminophor JSC, Stavropol, Russia), substituted pyrans (such as dicyanomethylene), coumarins (such as Coumarin 6 and Coumarin 30), rhodamines (such as Rhodamine B), oxazine, Exciton LDS series dyes (Exciton, Dayton, Ohio, USA), Nile Blue, Nile Red, DODCI, Epolight 5548 (Epolin, Inc. Newark, N.J., USA), Lumogen dyes (for instance: 083, 170, 240, 285, 305, 570, 650, 765, 788, and 850) (BASF Aktiengesellschaft, Ludwigshafen, Germany), other substituted dyes of this type, other oligorylenes, and dyes such as DTTC1, Steryl 6, Steryl 7, pyradines, indocyanine green, styryls (Lamba Physik Gmbh & Co. Kg, Gottingen, Del.), dioxazines, naphthalimides, thiazines, stilbenes, 1R132, 18144, IR140, Kodak Chemicals (Rochester, N.Y., USA) and Dayglo Sky Blue (D-286) and Columbia Blue (D-298) (DayGlo Color Corp., Cleveland, Ohio, USA). In still yet another embodiment, the dye emits in the infrared.

In yet another embodiment, a modulator is positioned adjacent the light concentrator. In other embodiments the light modulator is one of an LCD modulator, an LED modulator and a 3-D display.

In another aspect, the invention relates to a method of harvesting light from an illuminated electronic display. In one embodiment, the method for harvesting light includes providing a light source; providing a light concentrator comprising a substrate having a first surface, a second surface, an edge, and a luminescent dye; and providing a photovoltaic transducer positioned adjacent the substrate of the light concentrator. The index of refraction of the substrate is greater than the refractive index of air. Light passing through both the first and second surfaces of the substrates is polarized. A portion of light constrained within and traveling through the substrate of the light concentrator interacts with the photovoltaic transducer to produce electric current.

In one embodiment, the step of providing the light concentrator includes the step of forming the substrate by mixing the luminescent dye with the substrate material during formation and stretching the resulting substrate. In another embodiment, the step of providing the light concentrator includes the step of forming the substrate by coating the luminescent dye on a surface of the substrate material. In yet another embodiment, each molecule of the luminescent dye has a dipole having a longitudinal axis and the step of coating the luminescent dye on the surface of the substrate comprises coating the surface of the substrate such that the longitudinal axis of each of the dipole of each of the molecules of the dye lies in the plane of the surface and parallel to the longitudinal axis of the dipole of the other molecules of the dye.

In one embodiment, the step of providing the photovoltaic transducer includes positioning the photovoltaic transducer at the edge of the substrate. In yet another embodiment, the step of providing the photovoltaic transducer comprises positioning the photovoltaic transducer on one of the first and second surfaces of the substrate and wherein the index of refraction of the photovoltaic transducer is such that light traveling in the substrate escapes the surface of the substrate and enters the photovoltaic transducer. In one embodiment, portions of the substrate without a photovoltaic transducer are mirrored to retain the light in the waveguide.

### BRIEF DESCRIPTION OF THE DRAWINGS

The objects and features of the invention can be understood more completely by referring to the drawings described below and the accompanying descriptions.

FIG. 1 is a highly schematic diagram of an embodiment of a display system as know to the prior art;

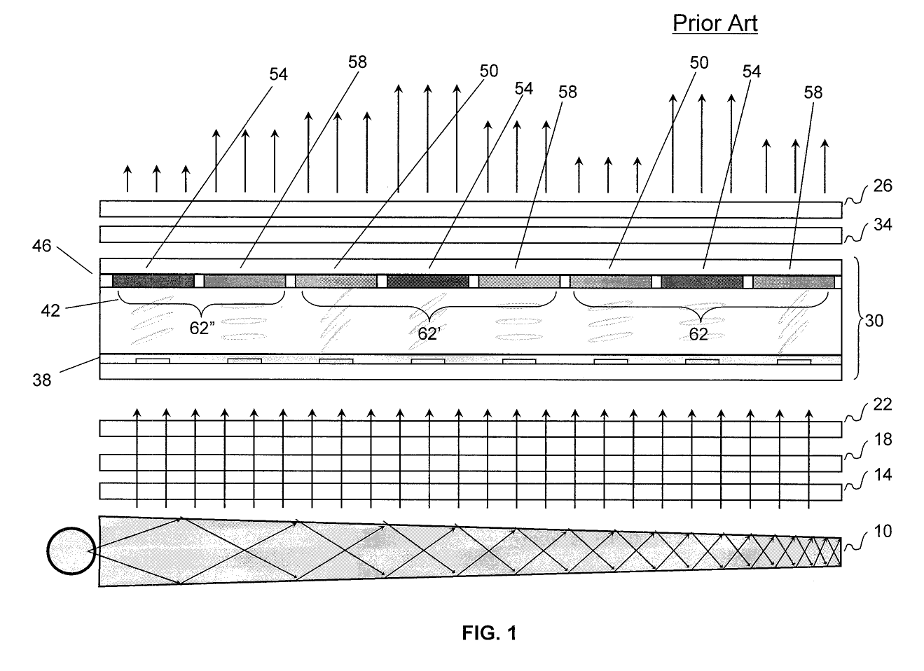

FIG. 2 is an exemplary graph of the percent absorption of light by a polarizer;

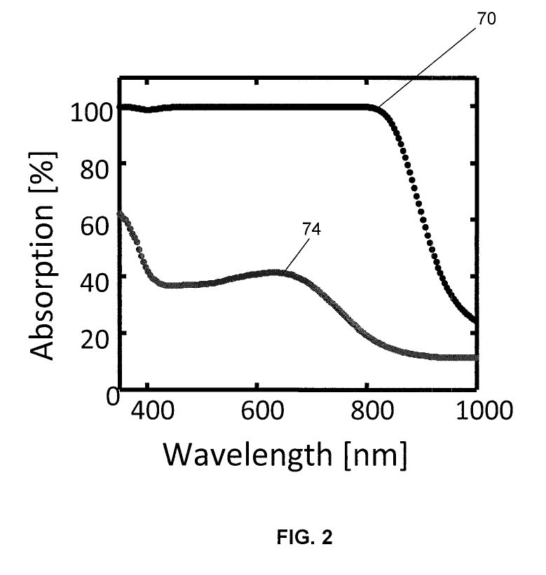

FIG. 3 is a schematic diagram of an embodiment of a Conventional Luminescent Solar Concentrator known to the prior art;

FIG. 4 is a schematic diagram of an embodiment of a Linearly Polarized Luminescent Solar Concentrator (LP-LSC) constructed according to an embodiment of the invention;

FIG. 5 is a schematic diagram of an embodiment of an LP-LSC polarizer with energy harvesting photovoltaic cells;

FIG. 6 is a schematic diagram of an embodiment of an organic light emitting diode (OLED) display with a circularly polarizing LP-LSC device adjacent to it; and

FIG. 7 is a schematic diagram of an embodiment of a LP-LSC with a photovoltaic device attached to its surface.

### DETAILED DESCRIPTION

The following description refers to the accompanying drawings that illustrate certain embodiments of the invention. Other embodiments are possible and modifications can be made to the embodiments without departing from the spirit and scope of the invention. Therefore, the following detailed description is not meant to limit the present invention. Rather, the scope of the present invention is defined by the claims.

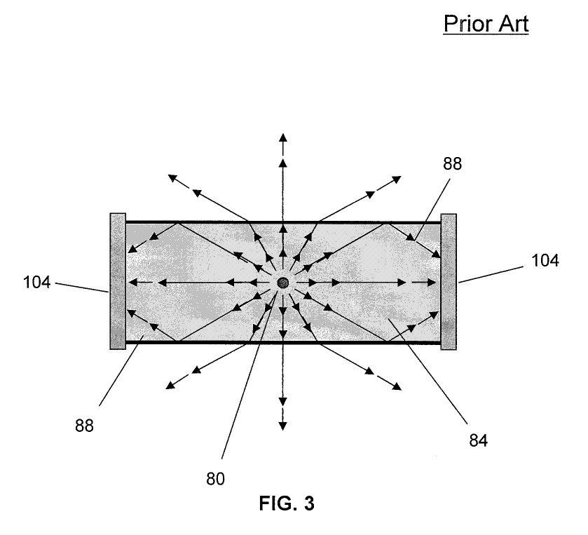

In brief overview and referring to FIG. 3, Conventional Luminescent Solar Concentrators (LSC) typically employ randomly oriented luminescent dye molecules 80 that are embedded in a transparent medium 84 that acts as a waveguide. The dye molecules 80 absorb diffuse light incident on the medium and re-emit these photons isotropically at a lower energy. A fraction of the photons that are re-emitted are trapped 88 within the medium waveguide through total internal reflection in a manner that is substantially identical to the operational principle of an optical fiber.

The reflection occurs because the refractive index of air is less than the refractive index of the medium 84. The combination of the refractive index difference and the angle at which the photon is emitted from the dye restricts the photons to the body of the concentrator. The photons eventually reach the edges of the concentrator where photovoltaic elements 104 are placed to collect the photons and convert them to electrical energy. When the area of the face of the waveguide is larger than the area of the edges, the light can be concentrated; an important attribute for efficient energy harvesting under low light conditions.

A second form of light concentrator is the Linearly Polarized Luminescent Solar Concentrators (LP-LSCs). Unlike conventional LSCs, LP-LSCs have aligned dichroic dye molecules. The usefulness of these molecules has been demonstrated previously with the aim of selectively coupling incident light to solar cells mounted perpendicularly to the polarized axis of an LSC, thereby improving the geometric gain of the LSC at the cost of poor off axis absorption.

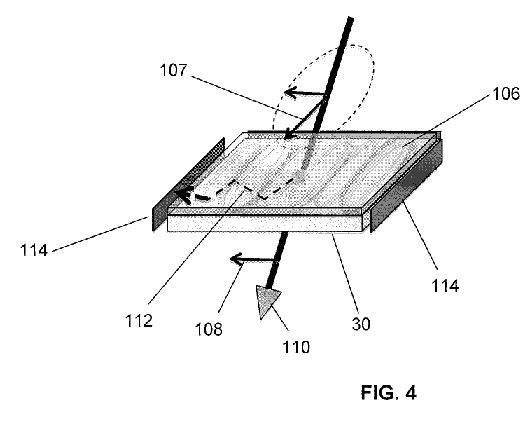

In one embodiment, FIG. 4, the dichroic luminescent dye molecules are linearly aligned on the surface of the substrate 106. The molecules of the LP-LSCs preferentially absorb light whose electric field vector is oriented parallel 107 to the dipole moment of the dye molecule. Light with an electric field vector perpendicular 108 to the dipole moment of the dye molecule is not absorbed and is transmitted through the material. This unabsorbed transmitted light 110 is therefore linearly polarized, just as in an ordinary polarizer.

Light which has an electric vector parallel to the dipole moment of the molecules is absorbed. However, instead of dissipating these absorbed photons of the light as heat, the luminescent dye molecules re-radiate the absorbed light. Some of this non-transmitted light that has been re-radiated by the dye molecules can be then be captured by the photovoltaic devices 114 and converted into electricity.

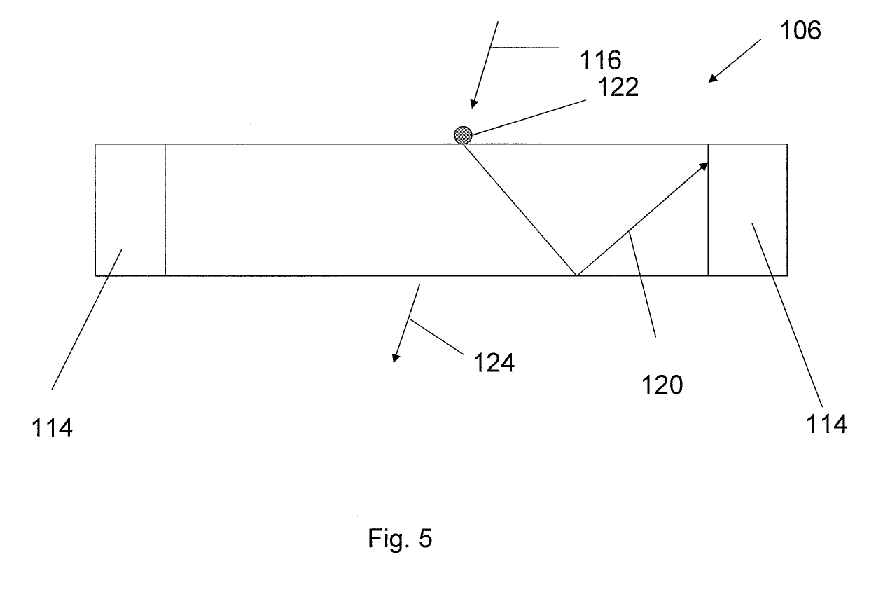

In the present invention, LP-LSCs are used as replacements for conventional linear polarizers in energy harvesting applications. Referring to FIG. 5, an embodiment of a LP-LSC is constructed with a plurality of photovoltaic devices surrounding the edges of the LP-LSC medium. Randomly polarized light 116 is incident on the surface of the medium and a portion of the light polarized parallel to the dipole axis of luminescent dye molecules 122 is absorbed and re radiated 120. The light that is polarized perpendicular to the dipole axis of the luminescent dye molecule is not absorbed and passes unaffected through the medium, resulting effectively in becoming linearly polarized light 124. The absorbed light which is reradiated at less than the critical angle is trapped by total internal reflection and eventually finds its way to the photovoltaic devices 114 at the edges of the device. In an embodiment in which only one edge includes a photovoltaic device, the other edges may be mirrored to capture additional light.

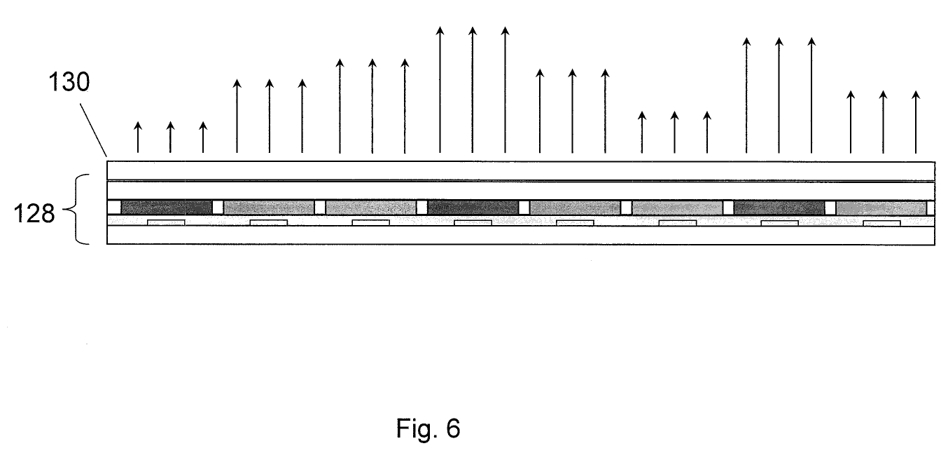

The invention may also be used with emissive types of displays. For example (FIG. 6), Organic Light Emitting Diode (OLED) displays typically include a polarizer 130 between the light emitting diodes and the viewer to improve contrast. This polarizer 130 is typically a circular polarizer which rotates the polarization of light passing through it by 45°. In operation, ambient light impinging on the display passes through the circular polarizer 130 and reflects off the OLED elements 128. The incoming light has its polarization rotated 45° and upon reflection, traveling back through the circular polarizer 130 has its polarization further rotated another 45°. The result is that the reflected light is absorbed by the circular polarizer. Usually this energy is also lost as heat. By replacing this polarizer 130 with a LP-LSC light harvesting polarizer of the invention adjacent a quarter wave plate, the combination is also a circular polarizer but one with the ability to convert the trapped ambient light into electricity.

In more detail, the LP-LSC is constructed of a transparent medium such as glass which has a refractive index η greater than the refractive index of air. In one embodiment, the surface of the transparent medium is coated with a luminescent dye molecule which has a linear dipole moment. In various embodiments, the dye molecules may be coated on either or both surfaces of the medium. In one embodiment, the luminescent dye is painted on the surface such that the dipoles of the individual molecules of the dye are aligned. Although glass is used in the embodiments described herein, any transparent material having a refractive index greater than air may be used, provided the substrate is chemically compatible with the luminescent dye, does not overly absorb the light passing through it, and does not change the polarization of the light passing through it.

An example of such a dye molecule is Coumarin-6. In one embodiment, Coumarin-6 (3-(2-Benzothiazolyl)-N,N-diethylumbelliferylamine) is a rod shaped molecule mixed within a polymerizable nematic liquid crystal (Paliococolor LC242 BASF, Ludwigshafen, Germany). In another embodiment, in order to improve the harvesting of radiation across the visible spectrum, the LP-LSC is constructed with several dye molecules that cascade in energy. In one embodiment, for this purpose, two dye molecules, 4-dicyanomethyl-6-dimethylaminostiryl-4H-pyran (DCM) and Coumarin 6 are used together on the surface of the substrate. In this embodiment, energy absorbed by the Coumarin 6 molecules is transferred to the DCM which then reemits the energy as light.

It should be kept in mind that although Coumarin 6 is mentioned in these embodiments, Coumarin 6 is only an example of a usable luminescent dye. Other dyes include fluorescent dyes and dyes which reradiate in the infrared. Dyes which reradiate in the infra-red are preferred because infrared radiation is not detected by the human eye and so such dyes do not affect the contrast in the display. Also, dyes that absorb in the infra-red can be aligned isotropically and do not need to possess dichroism. Various dyes include rare earth phosphors, organometallic complexes, porphyrins, perylene and its derivatives, organic laser dyes, FL-612 from Luminophor JSC, substituted pyrans (such as dicyanomethylene),other coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, pyradines, indocyanine green, styryls (Lambdachrome series), dioxazines, naphthalimides, thiazines, stilbenes, 18132, 18144, 112140, and Dayglo Sky Blue (D-286) and Columbia Blue (D-298).

In one embodiment, the LP-LSCs are created on a 1-mm-thick glass substrate with a refractive index, n=1.7. The glass substrates were cut with a dicing saw to obtain the desired dimension. The geometric gain of a LSC, G, is defined as the ratio of the face area versus edge area and is given by the formula:

G=(L/4d),

where L is the length of the LSC and d is the thickness (assuming the photovoltaic elements are placed on all four edges).

The glass is thoroughly cleaned with a detergent solution, de-ionized water and solvents. To create the alignment layer, a polyimide acid (SE410, Nissan Chemical Industries, LTD, Tokyo, Japan) is diluted to a ratio 1:1 with Solvent 25 (Nissan Chemical Industries, LTD), and spin-cast on the clean substrates in air with a ramp of 1000 rpm/sec and a spin speed of 2500 rpm for 30 seconds. Subsequently, the samples are baked on a hotplate in still air for 10 min at 80° C. and 60 minutes at 180° C. The coated samples are hand-rubbed with a velvet cloth to introduce alignment in the liquid crystal layer. The polymerizable nematic liquid crystal host is Paliocolor 242. The dyes used for the experiments are Coumarin 6 and DCM (both purchased from Sigma Aldrich, St. Louis, Mo., USA). These dyes possess a relatively high dichroic ratio and their photoluminescence efficiency is reasonably high (measured to be 78% and 60%, respectively). Coumarin 6 also possesses a large Stokes shift, which makes this dye especially suitable in an LSC. In one embodiment, Coumarin 6 as the sole dopant (at a 1% solid weight content), while in another embodiment both Coumarin 6 and DCM (both dyes at a 1% solid weight content) are used.

In the following description, all percentages of the separate components are given in weights relative to the total weight of the mixture. In a vial, a solution that contains Paliocolor (30%), Coumarin 6 (0.30%) or both DCM and Coumarin 6 (both at 0.30%) is prepared. To these powders, toluene is added (68.95%) and gently stirred. As a surfactant, BYK-361 (BYK USA, Wallingford, Connecticut, USA) is used (0.15%), which is taken from a pre-prepared solution of 5% BYK-361 dissolved in toluene. Lastly, Irgacure 184 (0.60%) (Ciba Specialty Chemicals, Tarrytown, N.Y., USA) is added as a photo initiator.

When the components are well dissolved, the solution is spin-cast on the pre-rubbed substrates. The samples are dried for 3 minutes at room temperature in still air, after which they are placed for 4 minutes on a hotplate at 80° C. (also in still air). The samples are cooled down to room temperature for 1 minute before placing them under a UV lamp (365 nm) for 3 minutes to cure. The spin speed was adopted to yield a film thickness that resulted in a peak absorption of 78% for light that is polarized parallel to the rubbing direction for the Coumarin 6 LP-LSCs. This film-thickness was estimated to be 1.1 microns thick through optical modeling.

In another embodiment, powdered Polyvinyl alcohol (PVA) (Sigma Aldrich, St. Louis, Mo., USA) is dissolved in de-ionized (DI) water at 4% (weight percentage) on a hotplate at 80C under continuous stirring. A water-soluble dye methylene Blue (Sigma Aldrich, St. Louis, Mo., USA) or Fluoresceine (Molecular Probes, Eugene, Oreg., USA) is added at 2 solid weight % to the PVA solution and mix well. The solution is then centrifuged for 10 minutes at 10000 rpm to remove air bubbles. This mixture is then cast in a mold or on a metal block and dried on a hotplate at 60° C. for 2 hours or in a oven at 60° C. for one hour to create a film is several hundreds of microns thick and can be easily be peeled of the mould or block. The thus created film is then stretched by hand or in a stretching machine. In one embodiment, water-soluble dyes with a high dichroic ratio are used.

In other embodiments, the alignment of the dye molecules may be accomplished by any of the following:

1. diffusing dye molecules into an aligned polymer sheet by placing the sheet in a bath with a dye solution or evaporating dyes which diffuse into the sheet and align themselves along the polymer backbone;

2. using liquid crystals mixed with dye molecules and an alignment layer to induce alignment in the liquid crystal layer (for instance using polyimide as alignment layer and inducing alignment through rubbing of the alignment layer prior to depositing and the subsequent polymerization of the liquid crystal/dye mixture;

3. using light to photo induce alignment in a liquid crystal/dye mixture coating (for instance with the use of a material class called azo dyes)which induce alignment in the liquid crystal layer with the luminescent dye;

4. using an electric field to induce alignment in a liquid crystal/dye coating and subsequently polymerizing the layer; and

5. using a magnetic field to induce alignment in liquid crystal/dye coating and subsequently polymerizing the layer.

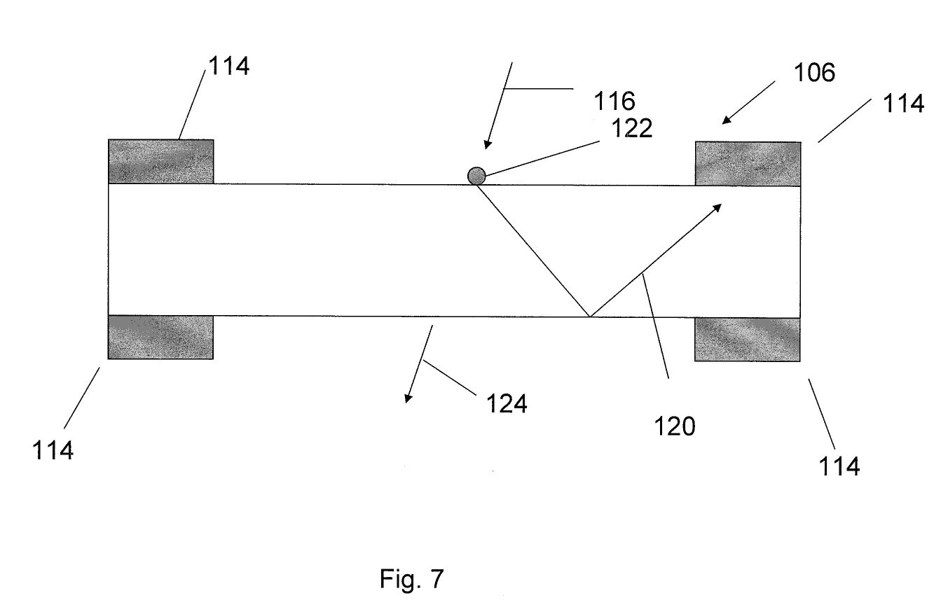

In another embodiment (FIG. 7), the photovoltaic devices 114 are located on a surface of the LP-LSC near the edges so as not to block the view. In this embodiment, the photovoltaic devices are either fabricated on the surface of the medium, are bonded to the surface of the medium with index of refraction matching material or are constructed of materials that match the index of refraction of the medium. In any of these cases, light reflecting 120 within the medium pass into the photovoltaic device 114 when the area in which the detector is located is traversed by the reflecting light. In this manner, light, not finding a significant difference in the refractive indices of the photovoltaic device and the medium, passes from the medium into the photovoltaic detector 114 to be absorbed. In embodiments in which the photovoltaic device is only on one portion of the surface of the substrate near the edge, other portions of the surface and of the edges may be mirrored to further capture the light.

Because an LP-LSC funnels the captured photons to photovoltaic elements, the elements can be placed at the edges of the substrate medium. Hence, this concept allows the photovoltaic transducers to be located in the frame of the display (or anywhere on the display which does not interfere with viewing), which minimizes their area, while leaving the entire front surface available for the display. That is, any light that does not pass through the medium to the viewer is recollected and turned into electricity and recycled for other further use. It should also be noted that ambient light radiating onto the display is also captured and furmeled to the photovoltaic receptors to further add to the electrical energy being harvested.

The examples presented herein are intended to illustrate potential and specific implementations of the invention. It can be appreciated that the examples are intended primarily for purposes of illustration of the invention for those skilled in the art. There may be variations to these diagrams or the operations described herein without departing from the spirit of the invention. For instance, in certain cases, method steps or operations may be performed or executed in differing order, or operations may be added, deleted or modified.

Variations, modification, and other implementations of what is described herein will occur to those of ordinary skill in the art without departing from the spirit and scope of the invention as claimed. Accordingly, the invention is to be defined not by the preceding illustrative description, but instead by the spirit and scope of the following claims.

What is claimed is:

1. A light harvesting electronic display comprising:
a light concentrator comprising:
a substrate having a first surface and a second surface and an edge; and
a luminescent dye; and
a photovoltaic transducer positioned adjacent the substrate of the light concentrator,
wherein the index of refraction of the substrate is greater than the refractive index of air,
wherein light passing through both the first and second surfaces of the substrate is polarized, and
wherein light constrained within and traveling through the substrate of the light concentrator interacts with the photovoltaic transducer to produce electric current.

2. The light harvesting electronic display of claim 1 wherein the luminescent dye comprises a plurality of different dye molecules.

3. The light harvesting electronic display of claim 1 wherein the photovoltaic transducer is located at the edge of the substrate,

4. The light harvesting electronic display of claim 1 wherein the photovoltaic transducer is located on one of the first and second surfaces of the substrate and wherein the index of refraction of the photovoltaic transducer is such that light traveling in the substrate escapes the surface of the substrate and enters the photovoltaic transducer.

5. The light harvesting electronic display of claim 1 wherein the luminescent dye is located on at least one of the first surface and the second surface of the substrate.

6. The light harvesting electronic display of claim 1 wherein the luminescent dye is located within the substrate.

7. The light harvesting electronic display of claim 6 wherein the LP-LSC polarizer includes a quarter wave plate to produce circularly polarized light.

8. The light harvesting electronic display of claim 1 wherein the dye comprises molecules having a dipole having a longitudinal axis.

9. The light harvesting electronic display 6 wherein the substrate is foamed by mixing the dye with the substrate material during formation and stretching the resulting substrate.

10. The light harvesting electronic display of claim 1 wherein the dye is selected from the group consisting of rare earth phosphors, organometallic complexes, porphyrins, perylene and its derivatives, organic laser dyes, FLL-612 from Luminophor JSC, substituted pyrans (such as dicyanomethylene),coumarins (such as Coumarin 6 and Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, pyradines, indocyanine green, styryls (Lambdachrome series), dioxazines, naphthalimides, thiazins, stilbenes, IR132, IR144, IR140, and Dayglo Sky Blue (D-286) and Columbia Blue (D-298).

11. The light harvesting electronic display of claim 1 wherein the dye emits in the infrared.

12. The light harvesting electronic display of claim 5 wherein the molecules of the dye are coated on one of the surfaces of the substrate such that the longitudinal axis of the dipole of each of the molecules of the dye lies in the plane of the surface and parallel to the axis of the dipole of the other molecules of the dye.

13. The light harvesting electronic display of claim 1 further comprising a modulator positioned adjacent the light concentrator.

14. The light harvesting electronic display of claim 13 wherein the light modulator is one of an LCD modulator, an LED modulator, and a 3-D display.

15. A method of harvesting light from an illuminated electronic display comprising the steps of:
providing a light source,
providing a light concentrator comprising:
a substrate having a first surface and a second surface and an edge; and
a luminescent dye; and
providing a photovoltaic transducer positioned adjacent the substrate of the light concentrator,
wherein the index of refraction of the substrate is greater than the refractive index of air, wherein light passing through both the first and second surfaces of the substrates is polarized, and
wherein a portion of light constrained within and traveling through the substrate of the light concentrator and interacts with the photovoltaic transducer to produce electric current.

16. The method of claim 15 wherein the step of providing the light concentrator comprises the step of forming the substrate by mixing the luminescent dye with the substrate material during formation and stretching the resulting substrate.

17. The method of claim 15 wherein the step of providing the light concentrator comprises the step of forming the substrate by coating the luminescent dye on a surface of the substrate material.

18. The method of claim 17 wherein each molecule of the fluorescent dye has a dipole having a longitudinal axis and the step of coating the luminescent dye on the surface of the substrate comprises coating the surface of the substrate such that the longitudinal axis of each of the dipole of each of the molecules of the dye lies in the plane of the surface and parallel to the longitudinal axis of the dipole of the other molecules of the dye.

19. The method of claim 15 wherein the dye comprises molecules having a dipole having longitudinal axis and wherein the step of providing a light concentrator comprises the step of placing a quarter wave plate adjacent the substrate.

20. The method of claim 15 wherein the step of providing the photovoltaic transducer comprises positioning the photovoltaic transducer at the edge of the substrate.

21. The method of claim 15 wherein the step of providing the photovoltaic transducer comprises positioning the photovoltaic transducer on one of the first and second surfaces of the substrate and wherein the index of refraction of the photovoltaic transducer is such that light traveling in the substrate escapes the surface of the substrate and enters the photovoltaic transducer.

22. The method of claim 15 wherein the step of providing the light concentrator comprises the step of aligning the molecules of the dye by a method selected from the group comprising:
diffusing the dye into an aligned polymer sheet,
stretching a polymer sheet that has a dye incorporated into it,
using a mixture of liquid crystal and dye with an alignment layer prior to polymerization,
inducing alignment using photoinduced alignment,
using an electric field; and
using a magnetic field.
